(19) United States
(12) Patent Application Publication
(10) Pub. No.: US 2009/0311877 A1
(43) Pub. Date: Dec. 17, 2009

(54) POST OXIDATION ANNEALING OF LOW TEMPERATURE THERMAL OR PLASMA BASED OXIDATION

(75) Inventors: CHRISTOPHER S. OLSEN, Fremont, CA (US); Yoshitaka Yokota, San Jose, CA (US); Rajesh Mani, San Jose, CA (US); Johanes Swenberg, Los Gatos, CA (US)

Correspondence Address: MOSER IP LAW GROUP / APPLIED MATERIALS, INC., 1030 BROAD STREET, 2ND FLOOR, SHREWSBURY, NJ, 07702, US

(73) Assignee: APPLIED MATERIALS, INC., Santa Clara, CA (US)

(21) Appl. No.: 12/143,626

(22) Filed: Jun. 20, 2008

Related U.S. Application Data
(60) Provisional application No. 61/061,603, filed on Jun. 14, 2008.

(51) Int. Cl. H01L 21/316

(52) U.S. Cl. 438/770; 257/E21.274

(57) ABSTRACT

Embodiments of the present invention provide methods of forming oxide layers on semiconductor substrates. In some embodiments, a method of forming an oxide layer on a semiconductor substrate includes forming an oxide layer on a substrate using an oxidation process having a first process gas at a first temperature less than about 800 degrees Celsius; and annealing the oxide layer formed on the substrate in the presence of a second process gas and at a second temperature. The oxidation process may be a plasma or thermal oxidation process performed at a temperature of about 800 degrees Celsius or below. In some embodiments, the post oxidation annealing process may be a spike or soak rapid thermal process, a laser anneal, or a flash anneal performed at a temperature of at least about 700 degrees Celsius, at least about 800 degrees Celsius, or at least about 950 degrees Celsius.

### CROSS-REFERENCE TO RELATED APPLICATIONS

This application claims benefit of U.S. provisional patent application Ser. No. 61/061,603, filed Jun. 14, 2008, which is herein incorporated by reference.

### BACKGROUND OF THE INVENTION

1. Field of the Invention

Embodiments of the present invention generally relate to semiconductor fabrication, and more particularly, to oxidation of a semiconductor device or its components.

2. Description of the Related Art

Semiconductor devices require thin oxide layers to be formed at various stages of their fabrication. For example, in transistors, a thin gate oxide layer may be formed as part of a gate stack structure. In addition, in some applications, such as in the fabrication of a flash memory film stack, a thin oxide layer may be formed surrounding the entire gate stack, for example, via exposing the stack to an oxidation process. Such oxidation processes have conventionally been performed either thermally or using a plasma.

Thermal processes for forming oxide layers (such as, for example, a gate oxide layer or a gate stack oxidation layer) have worked relatively well in fabrication of semiconductor devices having larger feature sizes typically used in the past. Unfortunately, as feature sizes are becoming much smaller and different oxides are employed in the next generation of advanced technologies, the high wafer temperatures required in thermal oxidation processes are problematic in that the sharp junction definitions which are now required become diffused at the higher temperatures (e.g., above about 800 degrees Celsius). Such a distortion of junction definitions and other features can lead to poor device performance or failure.

Thermal oxidation processes at higher temperatures (e.g., above about 800 degrees Celsius), for example, can cause unwanted metal oxidation in exposed metal layers (e.g., tungsten, tantalum). Additionally, for example, during sidewall polysilicon re-oxidation of a polysilicon gate structure, higher temperature oxidation can cause polysilicon grain coarsening that can lead to poor device performance.

Plasma oxidation processes used to form oxide layers have similar problems. For example, at high chamber pressures (e.g., 100 mTorr), growth rates can be low and at low chamber pressures (e.g., tens of mTorr), increased plasma ion energy leads to ion bombardment damage and defects in the oxide film.

For example, conventional oxidation processes often result in a defect known as bird's beak. Bird's beak refers to diffusion of the oxide layer into the layers of the film stack structure from the sides at the interface between adjacent layers, rounding off the corners of the adjacent layers. The resultant defect has a profile that resembles a bird's beak. The intrusion of the oxide layer into the active region of the memory cell (e.g., in flash memory applications, volatile memory applications, or the like) reduces the active width of the memory cell, thereby undesirably reducing the effective width of the cell and degrading the performance of the flash memory device.

Though there is a need for methods of growing oxide layers at lower temperatures (e.g., below about 800 degrees Celsius), there is no relaxation in the quality requirements for oxide layers grown at low temperatures. However, the quality of thermally grow oxide layers tend to degrade with a reduction in temperature.

Thus, there is a need for improved methods for oxidizing stacks of materials, whereby the oxide layers can be grown at lower temperatures while maintaining the required quality and reliability of the oxide layer

### SUMMARY

Embodiments of the present invention provide methods of forming oxide layers on semiconductor substrates. In some embodiments, a method of forming an oxide layer on a semiconductor substrate includes forming an oxide layer on a substrate using an oxidation process having a first process gas at a first temperature less than about 800 degrees Celsius; and annealing the oxide layer formed on the substrate in the presence of a second process gas and at a second temperature. The oxidation process may be either a plasma oxidation or a thermal oxidation process, and may be performed at a temperature of about 800 degrees Celsius or below. In some embodiments, the post oxidation annealing process may be a spike or soak rapid thermal process, a laser anneal, or a flash anneal, and may be performed at a temperature of at least about 700 degrees Celsius, at least about 800 degrees Celsius, or at least about 1050 degrees Celsius.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 depicts a flow chart of the inventive method in accordance with some embodiments.

FIGS. 2A-B illustrate stages of fabrication of a semiconductor structure in accordance with some embodiments of the present invention.

FIG. 3 illustrate stages of fabrication of a semiconductor structure in accordance with some embodiments of the present invention.

FIG. 4 depicts a cluster tool suitable for performing the present invention.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

Embodiments of the present invention provide methods for the fabrication of oxide layers on semiconductor substrates. The inventive processes may advantageously provide formation of oxide layers with low impurities, reduced dopant diffusion, reduced poly silicon grain coarsening, and reduced metal oxidation as compared to conventional processes. In some embodiments of the present invention, oxide layers, such as a gate stack oxidation layer may be formed (e.g., an oxide layer deposited atop and along the exposed surfaces of a gate stack) upon a gate stack as utilized in logic and memory (such as dynamic random access memory, or DRAM, and FLASH) applications. As used herein, the phrase “forming an oxide layer on a substrate” includes total, partial, and selective oxidation processes performed on flat substrates and on structures formed on substrates, such as, for example, the tops and/or sidewalls of gate stacks disposed on the substrate.

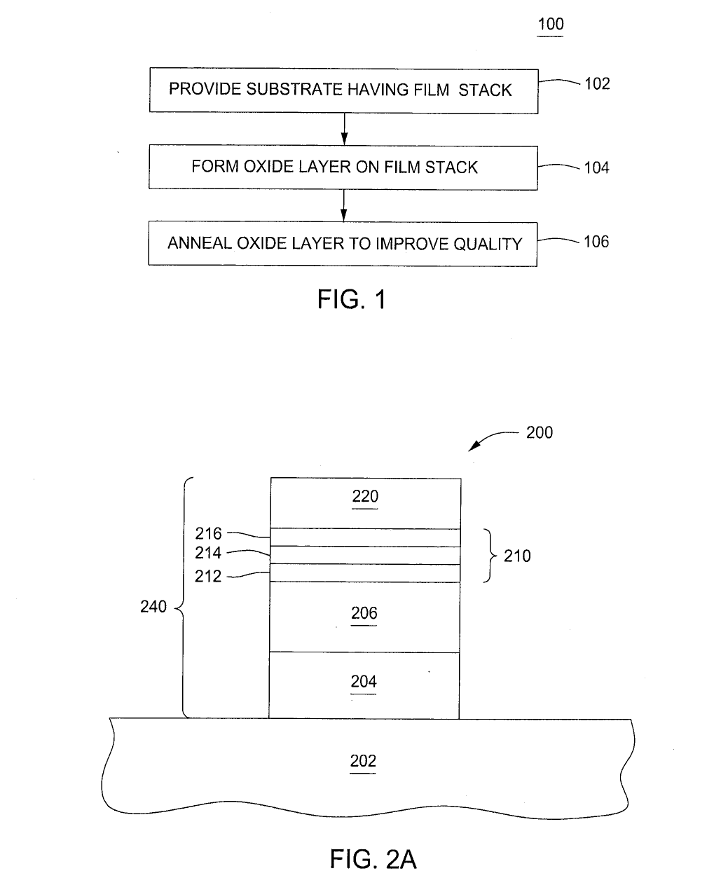

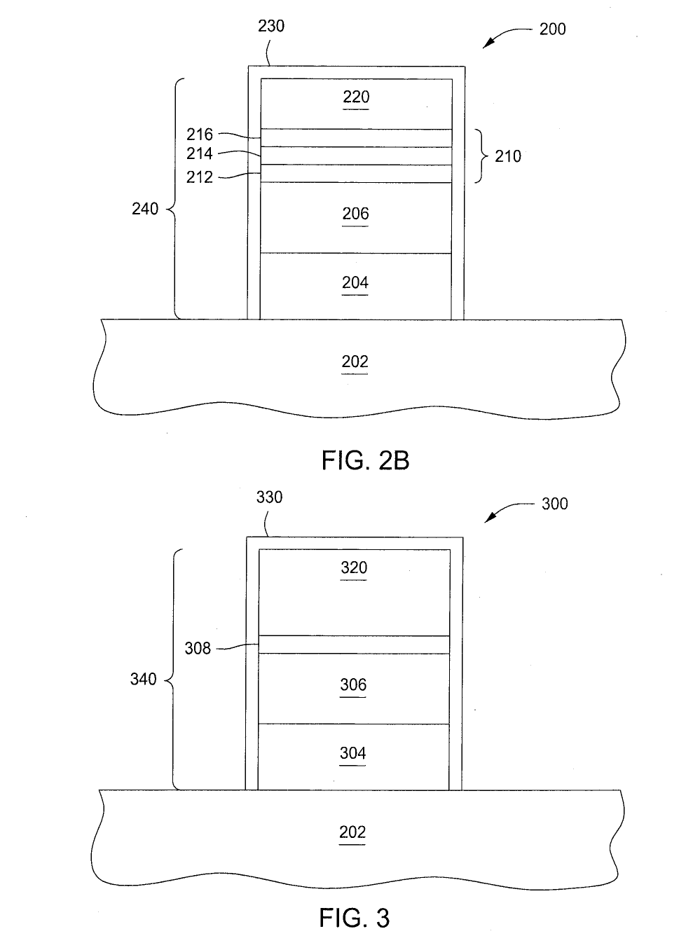

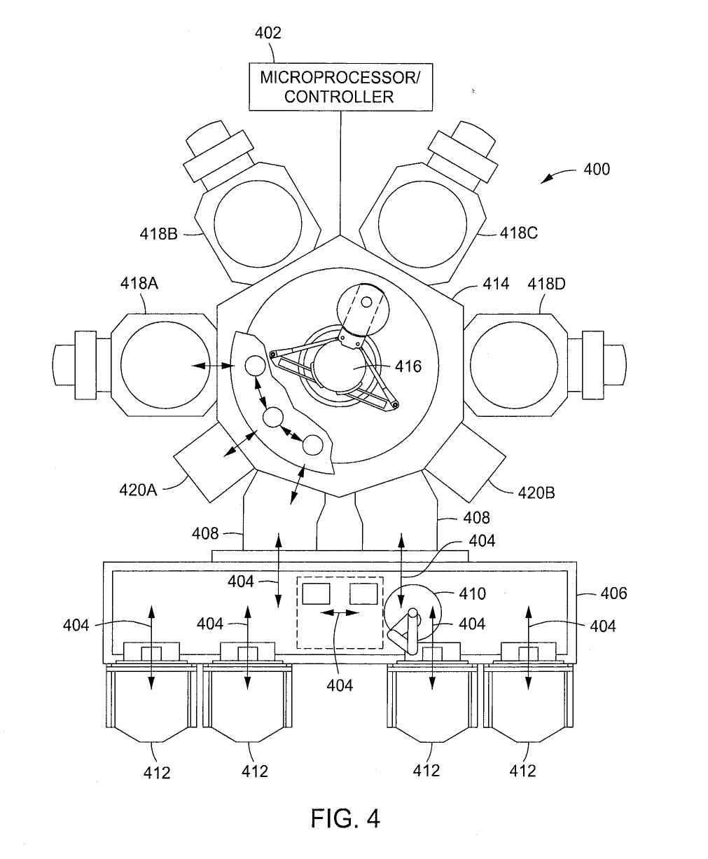

FIG. 1 depicts a method 100 for forming an oxide layer in accordance with embodiments of the present invention. The method 100 is described herein with respect to the structures depicted in FIGS. 2A-B and FIG. 3. FIGS. 2A-B depict the stages of fabrication of a semiconductor structure 200 including a film stack 240 formed over a semiconductor substrate 202. An alternative semiconductor structure 300 including a film stack 340 formed over a semiconductor substrate 202 is depicted in FIG. 3. The inventive methods may be practiced in any suitable process chamber, or combination of process chambers suitable for forming and annealing the oxide layer. Such suitable chambers include any chamber capable of performing plasma oxidation, thermal oxidation, rapid thermal processing (RTP) such as spike or soak RTP, laser anneal or dynamic surface anneal (DSA), flash anneal, or combinations thereof. Two such exemplary chambers are the DPN® and Radiance® chambers available from Applied Materials, Inc. of Santa Clara, Calif. Each process chamber used to practice the inventive methods may be operated individually, or as part of a cluster tool, such as one of the CENTURA® line of cluster tools, available from Applied Materials, Inc. One example of a suitable cluster tool is described below with respect to FIG. 4.

The process 100 begins at 102, where a substrate 202 is provided having a film stack 240 to be oxidized disposed thereupon. The substrate 202 may comprise a material such as crystalline silicon (e.g., Si<100> or Si<111>), silicon oxide, strained silicon, silicon germanium, doped or undoped polysilicon, doped or undoped silicon wafers, patterned or non-patterned wafers, silicon on insulator (SOI), carbon doped silicon oxides, silicon nitride, doped silicon, germanium, gallium arsenide, glass, sapphire, or the like.

The stack 240 may be any stack of materials to be oxidized where a reduction in bird's beak or other undesirable oxidative processes, such as excessive metal oxidation or dopant segregation, is desired. For example, in some embodiments, such as in flash memory applications, the stack 240 may be a gate stack of a flash memory cell comprising a tunnel oxide layer 204, a floating gate layer 206, a single or multi-layer dielectric layer comprising an interpoly dielectric (IPD) layer 210, and a control gate layer 220. A non-limiting example of the IPD is a multi-layer ONO layer comprising an oxide layer 212, a nitride layer 214, and an oxide layer 216, as illustratively shown in FIGS. 2A-B. The oxide layers 204, 212, 216 typically comprise silicon and oxygen, such as silicon oxide (SiO₂), silicon oxynitride (SiON), or the like. The nitride layer 214 typically comprises silicon and nitrogen, such as silicon nitride (SiN), or the like. In some embodiments, a multi-layer comprising SiO₂/Al₂O₃/SiO₂ can also be used as the IPD layer 210. The floating gate layer 206 and the control gate layer 220 typically comprise a conductive material, such as polysilicon, metal, or the like.

Alternatively, in some embodiments and as depicted in FIG. 3, a semiconductor structure 300 may be provided having a film stack disposed atop the substrate 202. The film stack may be a gate stack 340 comprising a tunnel oxide layer 304, a polysilicon gate layer 306, an nitride layer 308, and a metal electrode layer 320. The oxide layer 304 typically comprises silicon and oxygen, such as silicon oxide (SiO₂), silicon oxynitride (SiON), or the like. The nitride layer 308 typically comprises of titanium nitride (TiN) or tungsten nitride (WN). The metal electrode layer 320 is typically comprised of tungsten (W) or carbon- and/or nitrogen-containing tantalum (TaCₓ or TaNₓ or TaCxN_{y}, where x and y are integers≧1). The semiconductor structure 300 may be, for example, used in volatile memory applications, such as dynamic random access memory (DRAM).

Film stacks in other applications may be advantageously oxidized in accordance with the teachings provided herein, such as charge trap flash for non-volatile memory applications, or the like. For example, charge trap flash for non-volatile memory uses a SiO₂/SiN/Al₂O₃ gate stack with a metal electrode comprising tantalum nitride (TaN), titanium nitride (TiN), or tantalum carbide (TaCₓ) that may also benefit from sidewall oxidation after gate etch and a subsequent post oxidation anneal in accordance with the teachings disclosed herein.

In some embodiments, the inventive methods described herein may also be applied to high-k dielectric layers forming the gate oxide of logic devices such as a metal oxide semiconductor field effect transistor (MOSFET). The inventive methods may advantageously limit grain re-crystallization and grain growth, thus limiting dielectric breakdown in the device. Exemplary high-k dielectric materials may include hafnium oxide (HfO₂), hafnium silicon oxide (HfSiOₓ), hafnium silicon oxynitride (HfSiOₓN_{y}), aluminum oxide (Al₂O₃), and the like.

Next, at 104, an oxide layer 230 is formed on the gate stack 200 as illustrated in FIG. 2B (see also oxide layer 330 in FIG. 3). The formation of the oxide layer 230 includes forming the layer atop the control gate 220, and on the side wall of the gate stack. In some embodiments, oxide layers may be selectively formed, for example, on non-metal layers of a gate stack. The oxide layer 230 may be formed using suitable plasma oxidation or thermal oxidation methods. For example, in some embodiments, the oxide layer 230 may be formed thermally in an oxygen-containing environment, such as in an environment containing oxygen (O₂), ozone (O₃), water vapor (H₂O), hydrogen plus oxygen (H₂+O₂), or the like. In some embodiments, the oxide layer 230 may be formed in a plasma oxidation chamber by exposure to an oxygen-containing plasma.

In some embodiments, the oxide layer 230 may be formed from a first process gas comprising at least one of oxygen (O₂), ozone (O₃), water vapor (H₂O), hydrogen plus oxygen (H₂+O₂), or the like, and, optionally, an inert gas. The inert gas may include at least one of helium (He), argon (Ar), nitrogen (N₂), ammonia (NH₃) or the like. In some embodiments, the first process gas includes hydrogen and oxygen (H₂+O₂) with about 5% to 95% argon or other inert gas as a dissociative agent in the plasma. In some embodiments, the first process gas includes just oxygen (O₂) with about 5% to 95% argon (Ar) or other inert gas for non-selective oxidation. Typical total flows are between about 100 sccm to 1000 sccm when operating in the 1 mTorr to 1 Torr process regime. In embodiments where the process gas includes hydrogen and oxygen (H₂+O₂), hydrogen (H₂) may be provided at about 20-80% of the total gas mixture.

The oxide layer 230 formed at 104 may be performed at temperatures of less than or equal to about 800 degrees Celsius. In some embodiments, the temperature may be about 700 degrees Celsius or below. In some embodiments, the temperature may between about 400-500 degrees Celsius. At these lower temperatures, several effects may be minimized in semiconductor devices 200 and 300, such as oxide diffusion at the interface of adjacent layers (e.g., bird's beak), reduction of grain coarsening in polysilicon gate structures 206 and 306, and may negatively impact device performance, and/or reduction of grain coarsening or grain recrystallization in high-k dielectric gate oxides used in one or more of the semiconductor devices described above. In some embodiments, the oxide formation on metal electrodes or metal gates, for example, the metal electrode 320 of gate stack 340 in semiconductor device 300, may be limited by using the low temperature oxidation processes disclosed herein.

Next, at 106, a post-oxidation anneal may be performed on the oxide layer. The post-oxidation anneal facilitates improving the quality of the oxide layer formed by the low-temperature process, thereby minimizing the risk of poor device reliability or device failure due to a low quality oxide layer on the device. The post-oxidation anneal may include various high-temperature processes, such as a spike anneal, a soak anneal, a flash anneal, a laser anneal, or the like, and as described in more detail below. The post-oxidation anneal may be performed in any suitable process chamber configured to perform the above processes. Such chambers may include the RADIANCE® RTP chamber (e.g., for the spike or soak anneal) or the dynamic surface anneal (DSA) chamber (e.g., for the laser anneal), each of which are available from Applied Materials, Inc., of Santa Clara, Calif.

In some embodiments, the temperature of the post-oxidation anneal may be at least about 700 degrees Celsius, or at least about 800 degrees Celsius, or at least about 950 degrees Celsius. The post-oxidation anneal is described below with respect to the oxide layer 230 deposited on gate stack 240 in semiconductor device 200. However, the post-oxidation anneal methods described below may be applied to other oxide layers as disclosed herein (such as oxide layer 330 in FIG. 3, high-k dielectric gate oxides).

The post oxidation anneal at 106 may be performed in the presence of a second process gas in each of the post-oxidation anneal processes. The second process gas may include at least one of an oxidation gas, an inert gas, and/or a reducing gas. The oxidation gas may include at least one of oxygen (O₂), nitric oxide (NO), nitrous oxide (N₂O), or the like. The inert gas may include at least one of nitrogen (N₂), helium (He), argon (Ar), or the like. The inert gas may include a hydrogen-containing gas, such as, at least one of hydrogen (H₂), ammonia (NH₃), or the like.

In some embodiments, oxygen (O₂) may be less than 0.01% or up to 1% of the total flow rate of the second process gas provided. The oxygen (O₂) may be supplied at a reduced partial pressure to, for instance, prevent the decomposition of silicon dioxide (SiO₂) to silicon monoxide (SiO). In some embodiments, the partial pressure of oxygen (O₂) may be between about 1 milliTorr to about 10 Torr, or in some embodiments between about 5 milliTorr to about 10 Torr. In some embodiments, the second process gas may comprise oxygen (O₂) and nitrogen (N₂), and may be provided at a total gas flow rate of about 50 sccm, and at a flow rate ratio of O₂:N₂ of between about 1:100 and about 1:10,000. In some embodiments, the second process gas may comprise a reducing gas provided at a partial pressure of between about 10 milliTorr to about 100 Torr.

In some embodiments, the post-oxidation anneal may be performed by using a spike rapid thermal anneal (spike RTP) in the presence of the second process gas at a temperature (e.g., a desired temperature or peak temperature of the spike) greater than about 950 degrees Celsius. In some embodiments the temperature may be up to about 1200 degrees Celsius. In some embodiments, the temperature may be between about 1050 to about 1100 degrees Celsius, or between about 1050 to about 1200 degrees Celsius. In some embodiments, the temperature may be increased at a rate of about 100 to about 200 degrees Celsius per second until the desired temperature is achieved. A time period over which the spike anneal is applied may be defined as a time that it takes for the temperature to ramp from about 50 degrees Celsius below the desired temperature to the desired temperature and back to about 50 degrees Celsius below the desired temperature. In some embodiments, the time is about 3 seconds or less. In some embodiments, the time may be between about 0.9 to about 3 seconds. In some embodiments, the time may be between about 2 to about 3 seconds.

Alternatively, in some embodiments, the post-oxidation anneal may be performed by using a soak rapid thermal anneal (soak RTP) in the presence of the second process gas at a temperature (e.g., a desired temperature or peak temperature of the soak anneal) greater than about 700 degrees Celsius, or in some embodiments, up to about 800 degrees Celsius. In some embodiments, the temperature may be up to about 1150 degrees Celsius. In some embodiments, the temperature may be between about 1000 to about 1100 degrees Celsius. In some embodiments, the temperature may be increased at a rate of about 100 to about 200 degrees Celsius per second until the desired temperature is achieved. A time period over which the soak anneal is applied may be defined as the time that it takes for the temperature to ramp from about 5 degrees Celsius below the desired temperature to the desired temperature and back to about 5 degrees Celsius below the desired temperature. In some embodiments, the time is about 60 seconds or less. In some embodiments, the time may be between about 3 to about 60 seconds.

Alternatively, in some embodiments, the post-oxidation anneal may be performed by using a flash anneal in the presence of the second process gas at a temperature greater than about 950 degrees Celsius. In some embodiments, the temperature may be up to about 1300 degrees Celsius. In some embodiments, the temperature may between about 1100 to about 1300 degrees Celsius. The time of the flash anneal process may be defined as the time that, for instance, the semiconductor device 200 or 300 is exposed to the radiant energy of an arc lamp of a flash anneal system. In some embodiments, the exposure time is up to about 3 milliseconds. In some embodiments, the exposure time may be between about 1 to about 3 milliseconds.

Alternatively, in some embodiments, the post oxidation anneal may be performed by using a laser anneal (e.g., a dynamic surface anneal) process in the presence of the second process gas at a temperature greater than 950 degrees Celsius. In some embodiments, the second process gas used with the laser anneal process may be an inert gas, such as those discussed above. A method of laser annealing may include providing a laser beam which may be applied sequentially to at least some portions of the object being annealed, for instance, the film stack 240 or 340 of semiconductor devices 200 or 300. In operation, the laser beam may anneal a first portion of the film stack for a desired time, the substrate and/or laser beam may be translated, and the laser beam may anneal a second portion of the film stack for a desired time. The laser beam may be operated in a pulsed or continuous mode and over a desired range of wavelengths and intensities. Such conditions may be adjusted depending on, for instance, the absorbing properties (e.g., absorption cross section, extinction coefficient, or the like) of the material being annealed. In some embodiments, the temperature of each portion having the laser beam incident thereon may be up to 1350 degrees Celsius. In some embodiments, the temperature may be between about 1100 to about 1350 degrees Celsius. A time that the laser beam may be incident upon each portion may be about 1 millisecond or less. In some embodiments, the time may be between about 0.1 to about 1 milliseconds, or between about 0.2 to about 1 milliseconds.

Upon completion of the post-oxidation anneal at 106, the process generally ends and the substrate may be further processed as necessary to complete any structures or devices being fabricated thereon.

The inventive methods which comprise forming of an oxide layer and annealing the oxide layer may be practiced in the individual process chambers discussed above, in a standalone configuration, or as part of a cluster tool. A suitable cluster tool for practicing embodiments of the present invention is described below with respect to FIG. 4.

Generally, a cluster tool is a modular system comprising multiple chambers which perform various functions including, but not limited to, substrate center-finding and orientation, degassing, annealing, deposition and/or etching. According to some embodiments of the present invention, a cluster tool may include a plasma or thermal oxidation chamber configured to perform some embodiments of the low temperature oxidation processes disclosed herein. Additionally, a cluster tool may include at least one of a rapid thermal process, laser anneal, or flash anneal process chamber to perform embodiments of the post oxidation anneal (POA). The multiple chambers of the cluster tool may be mounted to a central transfer chamber which houses a robot adapted to transfer substrates between the chambers. The transfer chamber may be maintained at a vacuum condition and provides an intermediate stage for transferring substrates from one chamber to another and/or to or from one or more load lock chambers positioned at a front end of the cluster tool. Well-known lines of cluster tools which may be adapted for use with the present invention include the CENTURA® and VANTAGE® lines of cluster tools available from Applied Materials, Inc., of Santa Clara, Calif. The details of one such cluster tool, or staged-vacuum substrate processing system, is disclosed in U.S. Pat. No. 5,186,718, entitled “Staged-Vacuum Wafer Processing System and Method,” Tepman et al., issued on Feb. 16, 1993, which is incorporated herein by reference. However, the exact arrangement and combination of chambers may be altered for purposes of performing specific steps of a fabrication process, which includes the present oxidation and post oxidation annealing processes.

By way of illustration, one embodiment of a particular cluster tool 480 is shown in a plan view in FIG. 4. The cluster tool 400 generally comprises a plurality of chambers and robots and is preferably equipped with a microprocessor controller 402 programmed to carry out the various processing methods performed in the cluster tool 400. A front-end environment 406 is shown positioned in selective communication with a pair of load lock chambers 408. A pod loader 410 disposed in the front-end environment 406 is capable of linear and rotational movement (arrows 404) to shuttle cassettes of substrates between the load locks 408 and a plurality of pods 412 which are mounted on the front-end environment 406. The load locks 408 provide a first vacuum interface between the front-end environment 406 and a transfer chamber 414. Two load locks 408 are provided to increase throughput by alternatively communicating with the transfer chamber 414 and the front-end environment 406. Thus, while one load lock 408 communicates with the transfer chamber 414, a second load lock 408 communicates with the front-end environment 406. A robot 416 is centrally disposed in the transfer chamber 414 to transfer substrates from the load locks 408 to one of the various processing chambers 418 and service chambers 420. The processing chambers 418 may perform any number of processes such as physical vapor deposition, chemical vapor deposition, and etching while the service chambers 420 are adapted for degassing, orientation, cooldown and the like.

For example, a cluster tool configured to perform embodiments of the present invention may be configured to have at least one of the processing chambers 418 configured either a plasma oxidation or thermal oxidation chamber, configured to carry out at least portions of some embodiments of the present invention. Another one of the processing chambers 418 may be at least one of a rapid thermal process (RTP), laser annealing, or flash annealing process chamber. Of course, other equipment and configurations of processing chambers may be utilized in accordance with the teachings provided herein.

Thus, inventive methods for forming an oxide layer have been provided herein. The inventive methods advantageously limit undesirable oxidative processes, such as bird's beak formation, oxide/nitride/oxide (ONO) interpoly dielectric bird's beak, polysilicon grain coarsening, or excessive metal oxidation, which may arise during the stages of the fabrication process while facilitating the formation of high quality oxide films.

While the foregoing is directed to embodiments of the present invention, other and further embodiments of the invention may be devised without departing from the basic scope thereof, and the scope thereof is determined by the claims that follow.

1. A method of forming an oxide layer on a semiconductor substrate, comprising:
forming an oxide layer on a substrate using an oxidation process having a first process gas at a first temperature less than about 800 degrees Celsius; and
annealing the oxide layer formed on the substrate in the presence of a second process gas and at a second temperature of at least about 700 degrees Celsius.

2. The method of claim 1, wherein the oxidation process comprises at least one of plasma oxidation or thermal oxidation.

3. The method of claim 1, wherein annealing the oxide layer comprises performing at least one of a spike rapid thermal anneal, a soak rapid thermal anneal, a flash anneal, or a laser anneal.

4. The method of claim 1, wherein the substrate comprises a silicon-containing layer having a film stack formed thereon.

5. The method of claim 4, wherein the film stack comprises a tunnel oxide layer, a floating gate layer, a single or multi-layer dielectric layer, and a control gate layer.

6. The method of claim 4, wherein the film stack comprises a tunnel oxide layer, a polysilicon gate layer, a nitride layer, and a metal electrode layer.

7. The method of claim 1, wherein the oxide layer is a high-k dielectric layer.

8. The method of claim 1, wherein the first process gas comprises at least one of oxygen (O₂), ozone (O₃), hydrogen and oxygen (H₂+O₂), or water vapor (H₂O).

9. The method of claim 1, wherein the second process gas comprises at least one of oxygen (O₂), nitric oxide (NO), nitrous oxide (N₂O), nitrogen (N₂), hydrogen (H₂), ammonia (NH₃), or an inert gas.

10. The method of claim 1, wherein the second process gas comprises at least one of an oxidizing gas, a reducing gas, or an inert gas.

11. The method of claim 10, wherein the second process gas comprises an inert gas including at least one of helium (He) argon (Ar).

12. The method of claim 10, wherein the second process gas comprises oxygen (O₂) and nitrogen (N₂) provided at an O₂:N₂ flow rate ratio of between about 1:100 to about 1:10,000.

13. The method of claim 10, wherein the second process gas comprises an oxidizing gas provided at a partial pressure of between about 1 mTorr and about 10 Torr.

14. The method of claim 10, wherein the second process gas comprises a reducing gas provided at a partial pressure of between about 10 mTorr and about 100 Torr.

15. The method of claim 1, wherein the second temperature is at least about 950 degrees Celsius.

16. The method of claim 1, wherein annealing the oxide layer comprises a spike rapid thermal anneal, wherein the spike is applied for a period of about 0.9 to about 3 seconds at a temperature of between about 1050 to about 1200 degrees Celsius.

17. The method of claim 1, wherein annealing the oxide layer comprises a soak rapid thermal anneal, wherein the spike is applied for a period of about 3 to about 60 seconds at a temperature of between about 1000 to about 1200 degrees Celsius.

18. The method of claim 1, wherein annealing the oxide layer comprises a flash anneal, wherein the flash anneal is applied for a period of about 1 to about 3 milliseconds at a temperature of between about 1100 to about 1300 degrees Celsius.

19. The method of claim 1, wherein annealing the oxide layer comprises a laser anneal and is applied for a period of about 200 nsec to about 1 millisecond at a temperature of between about 1100 to about 1350 degrees Celsius.

20. The method of claim 19, wherein the laser anneal further comprises sequentially applying a beam of energy from a laser to one or more portions of the substrate for a period of about 200 nsec to about 1 millisecond at a temperature of between about 1100-1350 degrees Celsius.

21. The method of claim 1, wherein forming the oxide layer and annealing the oxide layer are performed in two separate chambers on mainframe where vacuum is not broken and the ambient is controlled between the two processes.

22. The method of claim 21, wherein forming the oxide layer and annealing the oxide layer are performed in a time of less than about 10 minutes.

23. The method of claim 21, wherein forming the oxide layer and annealing the oxide layer are performed in a time of less than about 5 minutes.

24. The method of claim 21, wherein forming the oxide layer and annealing the oxide layer are performed in a time of less than about 1 minute.

25. The method of claim 1, wherein forming the oxide layer and annealing the oxide layer are performed in the same chamber in a time of less than about 1 minute.
